(19) United States
(12) Patent Application Publication
(10) Pub. No.: US 2013/0001846 A1
(43) Pub. Date: Jan. 3, 2013

(54) CASSETTE JIG FOR WAFER CLEANING APPARATUS AND CASSETTE ASSEMBLY HAVING THE SAME

(75) Inventors: Jae-Hyun Park, Gumi-si (KR); Chung-Hyo Choi, Gumi-si (KR)

(73) Assignee: LG Siltron Incorporated, Gumi-si (KR)

(21) Appl. No.: 13/574,453

(22) PCT Filed: Jul. 15, 2010
(86) PCT No.: PCT/KR2010/004619

§ 371 Date: Aug. 3, 2012

(30) Foreign Application Priority Data
Jan. 22, 2010 (KR) 10-2010-0006096

(51) Int. Cl. H01L 21/673; B08B 13/00

(52) U.S. Cl. 269/289 R

(57) ABSTRACT

A cassette jig for a wafer cleaning apparatus is provided, comprising a jig body having an inner space designed to receive a first wafer therein; and a guide member mounted in the jig body and operative to guide a cassette to be installed in the jig body, the cassette having an inner space designed to receive a second wafer of a relatively smaller diameter than the first wafer therein.

### TECHNICAL FIELD

The present invention relates to a cassette used in a wafer cleaning apparatus, and more particularly, to a cassette jig that is applicable to a wafer cleaning apparatus for cleaning wafers of various sizes, and a cassette assembly having the same.

### CROSS-REFERENCE TO RELATED APPLICATION

This application claims priority to Korean Patent Application No. 10-2010-0006096 filed in Republic of Korea on Jan. 22, 2010, the entire contents of which are incorporated herein by reference.

### BACKGROUND ART

In a semiconductor wafer fabrication process, a cleaning process is a process for cleaning the surface of a wafer by removing various kinds of particles or metal contaminants remaining on the surface of the wafer.

Conventionally, the wafer cleaning process sequentially cleans and dries wafers 1 by means of a wafer cleaning apparatus, as shown in FIG. 1. Referring to FIG. 1, the wafer cleaning apparatus comprises a bath unit 10 for receiving a cleaning solution therein to sink a cassette where a plurality of wafers 1 are loaded, a transfer unit 20 for transferring the cassette, and a spin dryer unit 30 for drying the cleaned wafers.

A cassette 5 used in the wafer cleaning apparatus has an open top, and an inner space where a plurality of wafers 1 are loaded at uniform intervals. The cassette 5 has a body of a corresponding size to the diameter of the wafer, and guides the wafer 1 inserted therein from the top. For example, a cassette for loading a large diameter wafer of 200 mm diameter therein has a body sized to guide a 200 mm-diameter wafer.

However, the bath unit 10 receiving the cassette 5 therein, an the transfer unit 20 having an arm for holding the cassette 5, and the spin dryer unit 30 having a cradle 31 where the cassette 5 is placed, each has a fixed size to handle only wafers of a preset diameter, and thus, the conventional wafer cleaning apparatus has a drawback of cleaning wafers of one diameter only.

That is, in order to clean small diameter wafers such as 125 mm-diameter wafers or intermediate diameter wafers such as 150 mm-diameter wafers, it needs a separate cassette for such wafers, and a separate cleaning apparatus with the bath unit 10, the transfer unit 20 and the spin dryer unit 30, each unit being sized to conform to a cassette for such wafers.

As a result, a cleaning process for cleaning wafers of various diameters requires much installation costs and maintenance and repair costs.

### DISCLOSURE

### Technical Problem

The present invention is designed to solve the problems of the prior art, and therefore it is an object of the present invention to provide a cassette jig for a wafer cleaning apparatus that is configured to receive wafers of various sizes in the same body, and a cassette assembly having the same.

### Technical Solution

To achieve the object, the present invention discloses a cassette jig configured to mount a cassette unit therein, and a cassette assembly having the same.

A cassette jig for a wafer cleaning apparatus according to the present invention comprises a jig body having an inner space designed to receive a first wafer therein; and a guide member installed in the jig body and operative to guide a cassette to be mounted in the jig body, the cassette having an inner space designed to receive a second wafer of a relatively smaller diameter than the first wafer therein.

Preferably, the guide member is a pair of Teflon blocks installed at the opposing inner corner portions of the jig body in a width direction at one end of the jig body.

Preferably, the guide member has a crooked body corresponding to the corner portion of the jig body, and the guide member may have a guide groove for guiding an outer corner portion of the cassette to be inserted in the guide groove.

At least one cut-out hole may be formed at the side of the jig body for load reduction.

According to another aspect of the present invention, a cassette assembly for a wafer cleaning apparatus is provided, comprising a cassette jig including a jig body having an inner space designed to receive a first wafer therein, and a pair of guide members installed at the opposing inner corner portions of the jig body in a width direction at one end of the jig body; and a cassette unit having an inner space designed to receive a second wafer of a relatively smaller diameter than the first wafer therein, and mounted in the cassette jig under the guidance of the guide member.

### Advantageous Effects

According to the present invention, it can compatibly use a single cassette jig to clean both large diameter wafers and intermediate-small diameter wafers.

### DESCRIPTION OF DRAWINGS

The accompanying drawings illustrate the preferred embodiments of the present invention and are included to provide a further understanding of the spirit of the present invention together with the detailed description of the invention, and accordingly, the present invention should not be limitedly interpreted to the matters shown in the drawings.

FIG. 1 is a view illustrating a configuration of a typical wafer cleaning apparatus.

FIG. 2 is a view illustrating a configuration of a cassette assembly for a wafer cleaning apparatus according to an embodiment of the present invention.

FIG. 3 is a view illustrating a configuration a cassette assembly for a wafer cleaning apparatus according to another embodiment of the present invention.

FIG. 4 is an actual photograph of the cassette assembly for a wafer cleaning apparatus of FIG. 2, viewed from above.

FIG. 5 is a photograph of a cassette jig of FIG. 4, viewed from above.

FIG. 6 is an actual photograph of the cassette assembly for a wafer cleaning apparatus of FIG. 3.

FIG. 7 is a photograph of a cassette jig of FIG. 6, viewed from above.

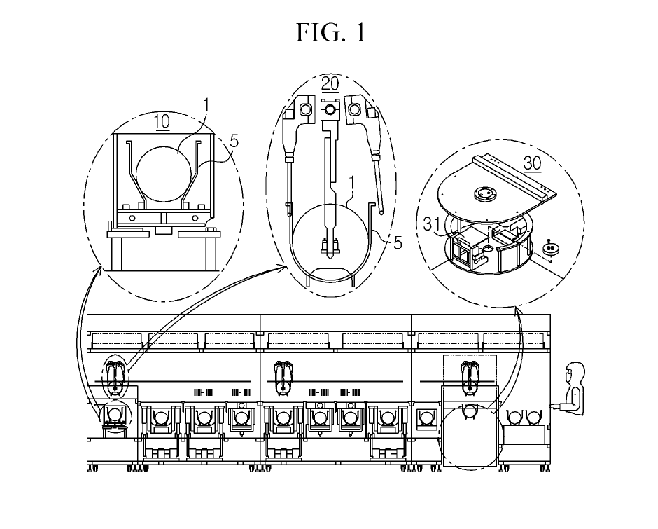

### BEST MODE

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

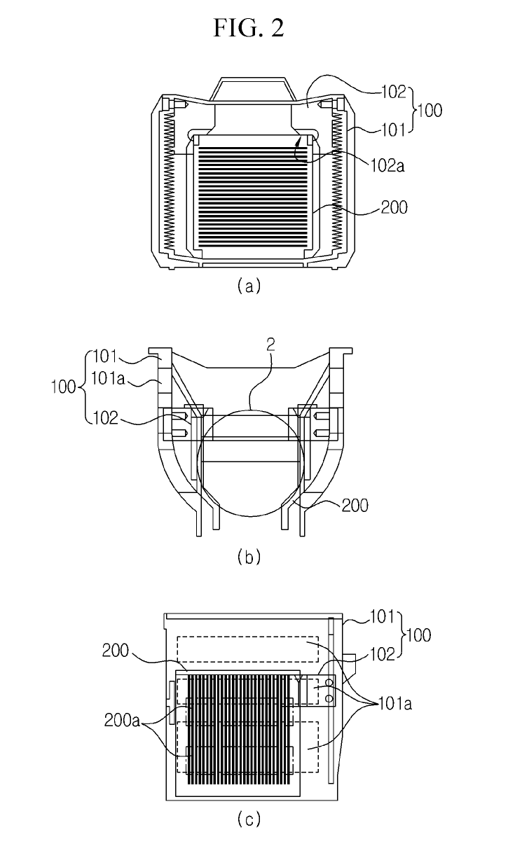

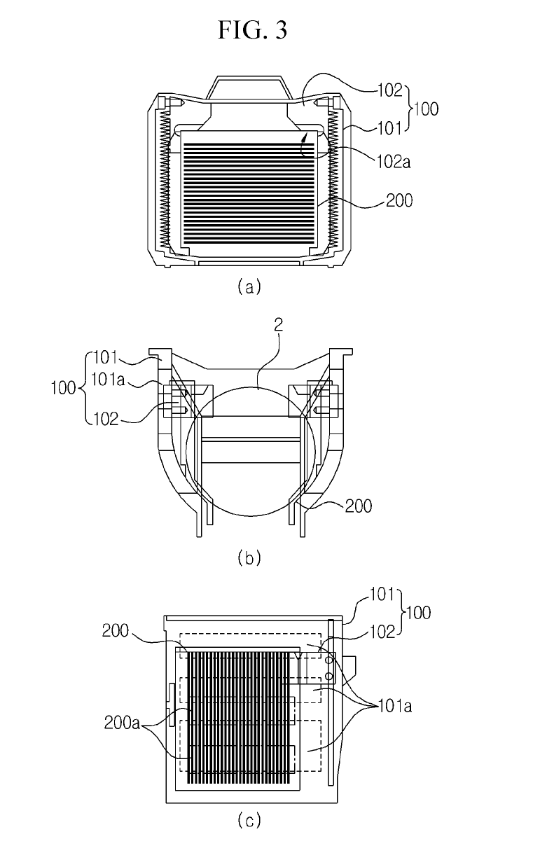

FIGS. 2 and 3 each is a view illustrating a configuration of a cassette assembly for a wafer cleaning apparatus according to a preferred embodiment of the present invention. In FIGS. 2 and 3, (a), (b) and (c) are a front side view, a top view and a side view, respectively.

Referring to FIGS. 2 and 3, the cassette assembly for a wafer cleaning apparatus comprises a cassette jig 100 having a jig body 101 and a guide member 102, and a cassette unit 200 mounted in the cassette jig 100.

The cassette jig 100 basically provides a cassette function for loading a relatively larger diameter wafer therein (hereinafter referred to as ‘a first wafer’ (not shown)), for example, of 200 mm diameter.

The jig body 101 of the cassette jig 100 has an open top, and an inner space where a plurality of first wafers are loaded at uniform intervals.

The guide member 102 of the cassette jig 100 provides a function for guiding a separate cassette unit 200 to be mounted in the jig body 101.

The guide member 102 is a guide block made with Teflon, and is installed at an inner corner portion of the jig body 101 by means of fastening means such as bolts and so on. The guide member 102 is provided such that a pair of guide members are each located at two opposing corner portions in a width direction of the jig body 101 at one end of the jig body 101.

The guide member 102 has a substantially crooked body of a ‘ [symbol] ’ shape conforming to the inner corner portion of the jig body 101, and is provided at an inner area of its body with a guide groove 102a for guiding an outer corner portion of the cassette unit 200 to be inserted in the guide groove 102a.

With regard to the cassette jig 100 of the above-mentioned configuration, FIGS. 5 and 7 show the actual cassette jig 100, into which 200 mm-diameter wafers can be inserted.

The cassette unit 200 is mounted in the cassette jig 100, and provides a cassette function for loading a wafer of a relatively smaller diameter than the first wafer therein, i.e. an intermediate-small diameter wafer (hereinafter referred to as ‘a second wafer’ 2) , for example, of 150 mm or 125 mm diameter.

With regard to the cassette unit 200 for receiving the second wafer 2 therein, the cassette unit 200 designed to receive 125 mm-diameter wafers therein is shown in FIG. 2, and the cassette unit 200 designed to receive 150 mm-diameter wafers therein is shown in FIG. 3.

As the cassette unit 200 is mounted in the cassette jig 100 of the cassette assembly for a wafer cleaning apparatus according to the present invention, preferably it has a means for reducing the total load of the cassette assembly for application to a cleaning apparatus with a bath unit, a transfer unit and a spin dryer unit. For this purpose, the jig body 101 of the cassette jig 100 and the cassette unit 200 have cut-out holes 101a and 200a of predetermined width and length at the side of their bodies, respectively.

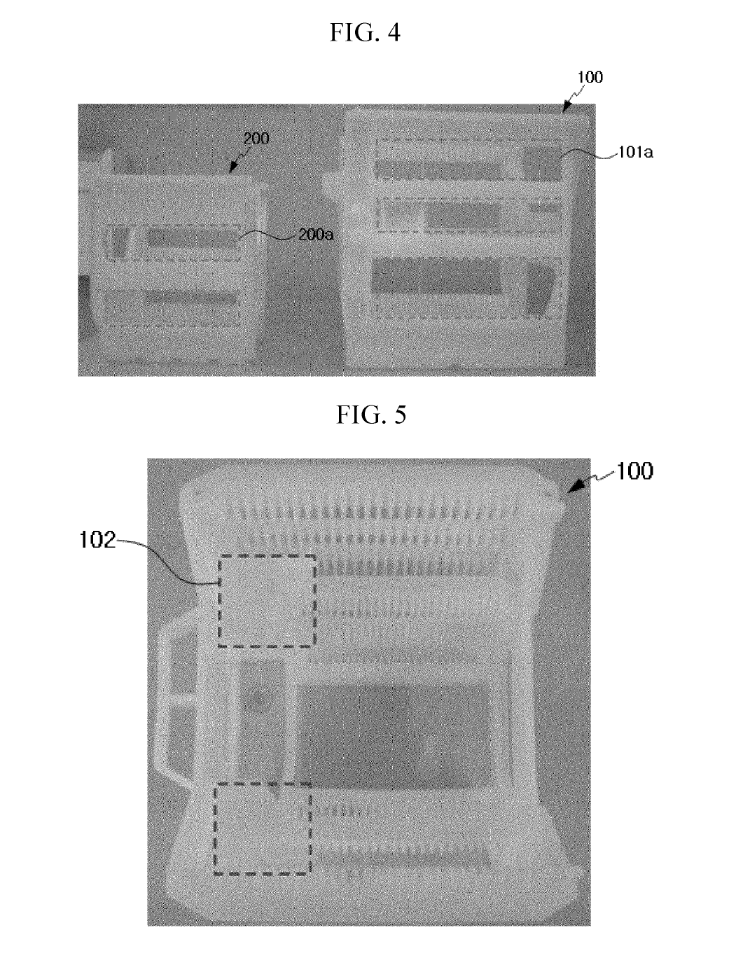

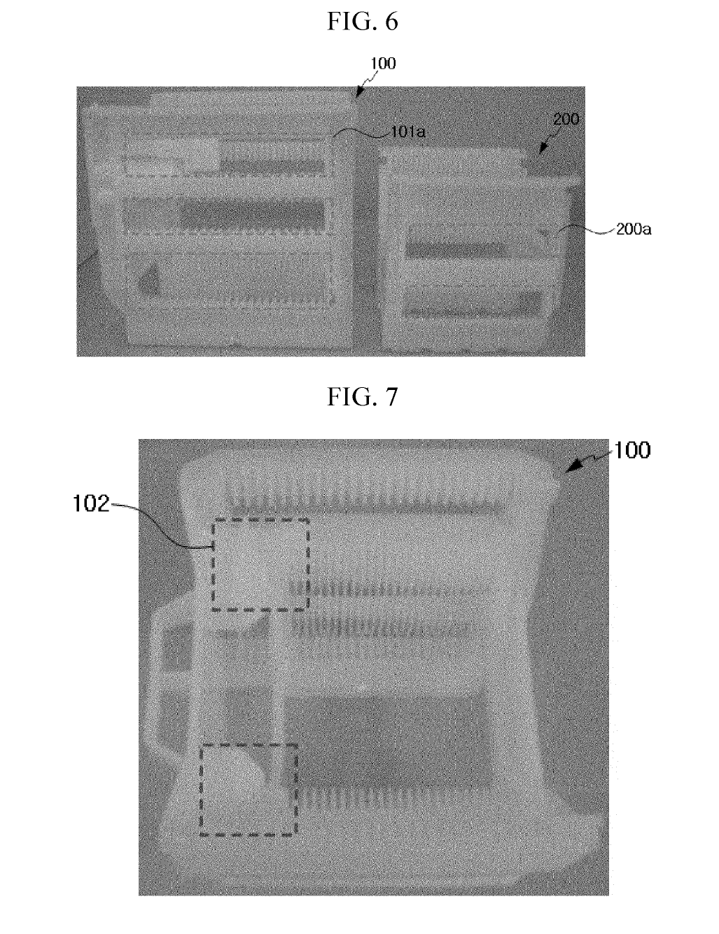

In this context, FIG. 4 shows that a cassette jig 100 designed to receive 200 mm-diameter wafers therein and a cassette unit 200 designed to receive 125 mm-diameter wafers therein are provided with cut-out holes 101a and 200a, respectively, and FIG. 6 shows that a cassette jig 100 designed to receive 200 mm-diameter wafers therein and a cassette unit 200 designed to receive 150 mm-diameter wafers therein are provided with cut-out holes 101a and 200a, respectively.

The cassette assembly for a wafer cleaning apparatus of the above-mentioned configuration basically provides a function for loading first wafers by means of the cassette jig 100, and if necessary, provides a function for loading second wafers by means of the cassette unit 200 mounted in the cassette jig 100.

As mentioned above, the outer part of the cassette jig 100 has a fixed size to conform to the size of wafers loaded in the cassette jig 100, and accordingly, even though the diameter of wafers loaded in the cassette jig 100 is changed, the cassette assembly according to the present invention conforms to the size of a bath unit, a transfer unit and a spin dryer unit of a conventional cleaning apparatus, so that it can be compatibly used to clean large diameter wafers and intermediate-small diameter wafers.

Although the present invention has been described hereinabove, it should be understood that the detailed description and specific examples, while indicating preferred embodiments of the invention, are given by way of illustration only, since various changes and modifications within the spirit and scope of the invention will become apparent to those skilled in the art from this detailed description.

### INDUSTRIAL AVAILABILITY

According to the present invention, it can compatibly use a single cassette jig to clean large diameter wafers and intermediate-small diameter wafers, and thus, when a wafer of different diameter is to be cleaned, it does not require additional arrangements to a bath unit, a transfer unit and a spin dryer unit of a cleaning apparatus, thereby reducing installation costs and maintenance and repair costs.

What is claimed is:

1. A cassette jig for a wafer cleaning apparatus, comprising:
a jig body having an inner space designed to receive a first wafer therein; and
a guide member mounted in the jig body and operative to guide a cassette to be installed in the jig body, the cassette having an inner space designed to receive a second wafer of a relatively smaller diameter than the first wafer therein.

2. The cassette jig for a wafer cleaning apparatus according to claim 1,
wherein the guide member is a pair of Teflon blocks installed at the opposing inner corner portions of the jig body in the width direction at one end of the jig body.

3. The cassette jig for a wafer cleaning apparatus according to claim 2,
wherein the guide member has a crooked body corresponding to the corner portion, and
wherein the guide member has a guide groove for guiding an outer corner portion of the cassette to be inserted in the guide groove.

4. The cassette jig for a wafer cleaning apparatus according to claim 1,
wherein at least one cut-out hole is formed at the side of the jig body for load reduction.

5. A cassette assembly for a wafer cleaning apparatus, comprising:
a cassette jig including a jig body having an inner space designed to receive a first wafer therein, and a pair of guide members installed at the opposing inner corner portions of the jig body in a width direction at one end of the jig body; and
a cassette unit having an inner space designed to receive a second wafer of a relatively smaller diameter than the first wafer therein, and mounted in the cassette jig under the guidance of the guide member.

6. The cassette assembly for a wafer cleaning apparatus according to claim 5,
wherein the guide member is a Teflon guide.

7. The cassette assembly for a wafer cleaning apparatus according to claim 5,
wherein the guide member has a crooked body corresponding to the corner portion, and
wherein the guide member has a guide groove for guiding an outer corner portion of the cassette unit to be inserted in the guide groove.

8. The cassette assembly for a wafer cleaning apparatus according to claim 5,
wherein at least one cut-out hole is formed at the side of at least one of the jig body and the cassette unit for load reduction.
